(19) United States
(12) Patent Application Publication
(10) Pub. No.: US 2006/0000806 A1
(43) Pub. Date: Jan. 5, 2006

(54) Substrate carrier for surface planarization

(76) Inventors: Reza M. Golzarian, Beaverton, OR (US); Herng Liu, Tigard, OR (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/883,404

(22) Filed: Jun. 30, 2004

(51) Int. Cl. B44C 1/22; C23F 1/00; H01L 21/306

(52) U.S. Cl. 216/84; 216/86; 156/345.12; 156/345.13

(57) ABSTRACT

A substrate processing apparatus equipped to employ one or more actuators to generate localized deflections in a process side of a substrate to enhance and control material removal is provided.

### FIELD OF THE INVENTION

Embodiments of the present invention relate to a substrate carrier adapted to enhance substrate surface planarization in processes such as chemical mechanical planarization (CMP).

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings.

FIG. 1 illustrates a perspective view of a substrate processing apparatus in accordance with an embodiment of the present invention;

FIG. 2 illustrates an enlarged cross-sectional view of a substrate processing apparatus in accordance with an embodiment of the present invention;

FIG. 3 illustrates an enlarged cross-sectional view of a substrate processing apparatus in accordance with an embodiment of the present invention;

FIG. 4 illustrates an enlarged cross-sectional view of a substrate processing apparatus in accordance with an embodiment of the present invention;

FIG. 5 illustrates a method of enhancing CMP using actuator to cause localized deflections in accordance with and embodiment of the present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Embodiments of the present invention relate to the processing of substrates such as semiconductor wafers and/or metalized layers in semiconductor devices, using a substrate carrier configured to provide localized control of surface planarization during a CMP process. Embodiments of the present invention may allow for the processing of a substrate using, for example, very low pressures, high rotational velocity, and manipulation of other parameters that may be particularly useful for planarization of ultra low-K substrates to help resist mechanical damage during the substrate processing step.

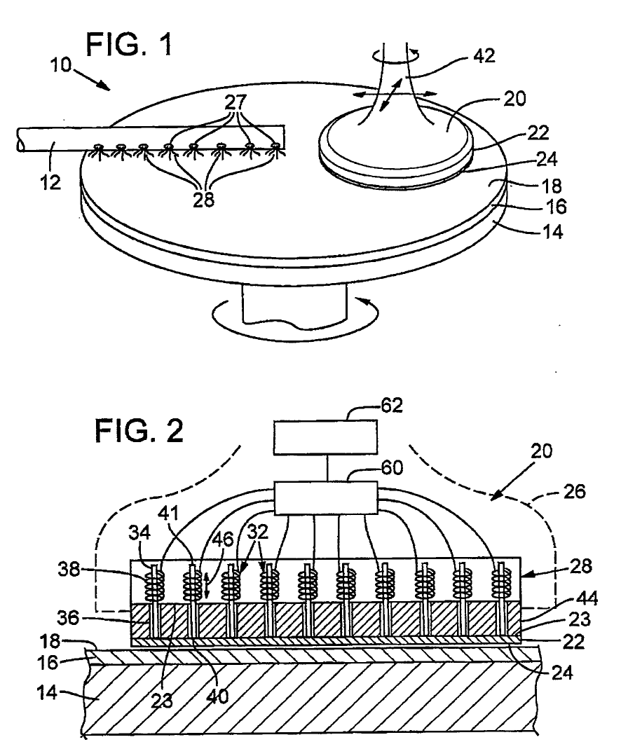

FIG. 1 illustrates a perspective view of a substrate processing apparatus in accordance with an embodiment of the present invention. A CMP apparatus 10, may include a slurry/solution delivery system 12, a processing element 16 and a processing element carrier 14. Processing element 16 may be, for example, a polishing pad and the processing element carrier 14 may be a rotatable platen adapted to provide a substantially planar turntable to support a processing element 16.

Substrate carrier 20 may be configured to support a substrate 22 in a substantially opposing relationship with the processing element 16 (processing relationship). Substrate carrier 20 may also be adapted to movably position the substrate 22 in an urging engagement with the processing element 16 to effect a planarization or polishing of the process side 24 of substrate 22. Substrate carrier 20 may be configured to rotate, oscillate, or otherwise move as needed to induce processing of the process side 24 of substrate 22.

Slurry delivery system 12 may include one or more nozzles 27 positioned adjacent the surface 18 of processing element 16 for the dispensing of a slurry/solution 28 thereon. During a polishing/planarization step, for example, a slurry 28 containing a liquid, such as, but not limited to, deionized water for oxide polishing and a pH adjuster, such as potassium hydroxide also for oxide polishing, can be supplied to the surface 18 of processing element 16 by the slurry arm 12, and may help facilitate removal of material from process side 24 of substrate 22. Slurry 28 can also include abrasive particles, including, but not limited to, silicon dioxide for oxide polishing.

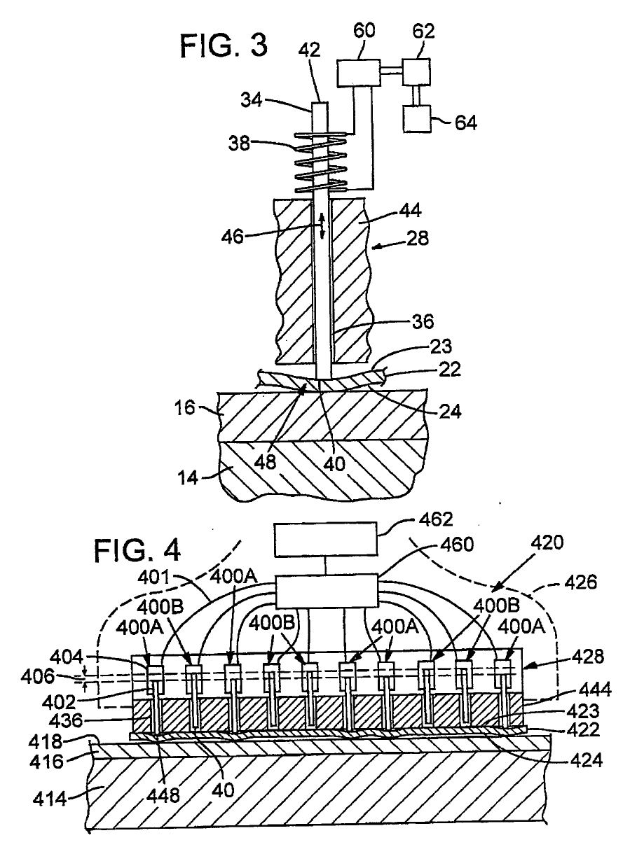

FIG. 2 illustrates an enlarged cross-sectional view of a substrate processing apparatus in accordance with an embodiment of the present invention and FIG. 3 illustrates an enlarged view of the substrate carrier of FIG. 2 in accordance with an embodiment of the present invention. Substrate carrier 20 may include a housing 26 having a cavity 28 disposed therein, and a backing plate 44. Backing plate 44 may be configured to couple to a backside 23 of a substrate 22 and assist in retaining substrate 22 during processing. Substrate 22 may have a process side 24 that may require polishing or planarizing to remove certain layers of material.

Substrate carrier 20 may also include an array of actuators 32 disposed within the body of housing 26, and in the illustrated embodiment may be disposed in cavity 28 of housing 26. Actuators 32 may be adapted to independently and controllably urge one or more localize portions of substrate 22 to be in respectively the same or different greater degrees of processing engagement with process element 16. The one or more localized deflections of the substrate may in turn enhance planarization at that point or points. Actuators 32 may take a number forms and be actuated or driven in several ways.

In one embodiment of the invention, actuators 32 may be electrically driven and include, for example, an impingement pin 34 that has a first end 40 and a second end 41. Impingement pin 34 may project from within cavity 28 through an actuator bore 36 in backing plate 44 in a linearly movable fashion. First end 40 may be configured for engagement with the backside 23 of substrate 22. A portion of the impingement pin 34 may also pass through a solenoid 38, such as an electrically conductive coil winding, also housed within cavity 28. Solenoid 38 may be configured to selectively move impingement pin 34 within actuator bore 36 by changing the current magnitude and/or flow through solenoid 38.

The solenoid 38 may be energized by a controllable electricity source 60, such that the current supplied to coil 34 may be varied. Applying a current may cause first end 40 of impingement pin 34 to push against backside 23 such that a local deflection of substrate 22 may result. Such a deflection may urge the process side of the localized deflection to be in greater contact with processing element 18 and thus may enhance the planarization of the localized area. Likewise, changing the current (e.g. reversing the current flow) may result in a retraction of impingement pin 34, which in turn may relive the deflection to reduce the enhanced planarization caused by the local deflection.

Controlling the deflections of certain substrate portions may provide for selective local control of material removal from the process side 24 of substrate 22. As illustrated in FIG. 3, impingement pin 34 may extend through solenoid windings 38 and through actuator bore 36 such that first end 40 is in a deflecting engagement with substrate 22 resulting in a localized deflection 48. To control localized deflection 48, the electricity source 60 may be coupled to a controller 62. Controller 62 may control the magnitude and direction of current flow through solenoid windings 38, which may in turn cause the impingement pin 32 to linearly move as shown by directional arrows 46.

In one embodiment of the present invention, controller 62 may include, but is not limited to, an electronic computer. The computer may include, a CPU, memory, buses, I/O ports all suitably interconnected to electricity source 60 and configured to control the linear actuation of impingement pin 34. In one embodiment of the invention, software instructions and data can be coded and stored within the memory for causing the controller 62 to generate suitable signals to each solenoid 38 to control the movement of the first end 40 of the impingement pin 34 into and out of forcible engagement with backside 23. In alternate embodiments, application specific integrated circuits (ASIC), or other special purpose hardware may be employed to implement controller 62.

In one embodiment of the present invention, an end point detection device 64 may also be in communication with controller 62, and configured to detect and/or monitor the processing of the process side 24 of substrate 22. End point detection device 64 may be a suitable device currently used.

During the processing of substrate 22, should a localized area of substrate 22 need more aggressive polishing, as may be determined by end point detection device 64, the end point detection device 64 may send a signal to controller 62. Controller 62 may in turn cause electricity source 60 to modify/change the current to solenoid 38 as needed to cause the first end 40 of impingement in 34 to increase engaging pressure against the backside 23. This increased pressure may generate localized deflection 48, which in turn may enhance localized planarization of substrate 22. Upon reaching a desired planarization, again as may be detected by end point detection device 64, the reverse process may occur such that the amount of deflection may be reduced to reduce the amount of localized planarization.

FIG. 4 illustrates an enlarged cross-sectional view of a substrate carrier in accordance with an embodiment of the present invention. Substrate carrier 420 may have a housing 426 configured to retain a substrate 422 in a generally opposing relationship with a processing element 416 for planarizing/polishing of a process side 424. Substrate carrier 420 may include a cavity 428, and a backing plate 444, which may be adapted to retain substrate 422 in a processing relationship with process element 416 during planarization.

A plurality of actuators 400 (shown in both configurations A and B) may be positioned within cavity 248 of substrate carrier 420. Actuators 400 may be pneumatically driven, and include a movable piston 402 and a cylinder 404 that may be chargeable with air or other gas. Piston 402 may be configured to controllably slide in and out of cylinder 404 based on a signal input and a charging and exhausting of air from cylinder 404. Piston 402 may be configured to extend from cylinder 404 through actuator bore 436 in backing plate 444, and have a first end 440 configured for engagement with backside 423. Actuators 400 may be in communication with a pneumatic controller 460, which may selectively and independently control the actuation of pistons 402 by controlling the supply of air to individual pneumatic actuators 400 through supply lines 401.

CMP systems typically include a number of pneumatically operated subsystems and actions. Accordingly, in one embodiment, the pneumatic source to the pneumatic controller 460 may be from a general source responsible for those other pneumatic operations. In one embodiment, an independent pneumatic source, such as a compressor or pressurized cylinder, may be in communication with pneumatic controller 460 and may also be incorporated in the substrate carrier 420.

To urge enhanced removal of material from a localized area of the process side 424 of substrate 422, pneumatic controller 460 may activate pneumatic actuator 400, such that piston 402 is forced out of cylinder 404, first end 440 may be urged against backside 423 of substrate 422. Illustrated as pneumatic actuator configuration 400A, when piston 402 is in the extended position, it may cause a localized deflection 448 in substrate 422. Localized deflection 448 may enhance the removal of material at the area of deflection on the process side 424, as this area will be in a greater degree of contact with processing element 416.

In areas where material from the process side 424 does not need further removal, for example, the pneumatic actuator 400 may be in state where air from the cylinder 404 is removed such that piston 402 may at least partially retract into cylinder 404, as shown by pneumatic actuator configuration 400 B. With piston 402 retracted, there may be no affirmative substrate deflection, which in turn may de-emphasize contact between a localized area and process element 416. Piston 402 may be controllably retracted and extended between the range of movement 406, such that the amount of localized deflection 448 may be controlled anywhere from a maximum deflection state to a minimum or no deflection state, depending on the processing status.

An end point detector 462 may be utilized to monitor the planarization of the process side 424 of substrate 422. End point detection device 462 may generate signals corresponding to various planarization states, and be configured to send such signals to pneumatic controller 460. Depending on the state of planarization (uniformity, degree of material removal, overall planarization, etc.), pneumatic controller 462 may in turn selectively control actuation of the independent pneumatic actuators, and thus control the level of enhanced planarization and material removal at various localized areas on the process side 424.

In one embodiment of the invention, the actuator bores 436 may be configured to be controllably placed under a vacuum. Thus, when the actuators are not pushing against or in contact with the substrate backside 23, the substrate may be held against the backing plate at the localized area. Further, if desired, the vacuum may cause a localized inverse deflection in order to de-emphasize the removal of material in that localized area.

In embodiments of the present invention, additional actuators may be used having different actuation mechanisms, including, but not limited to a screw drive mechanism, hydraulic actuated systems, magnetically controlled systems, as well as other drive mechanisms that may allow for selective localized deflection of the substrate 422 to enhance material removal from localized areas. The number and configuration of actuators used in accordance with embodiments of the present invention may vary depending on a variety of factors, including the substrate material being processed (e.g. material composition, thickness, number of layers, etc.), the processing stage, substrate size, and the like.

Further, embodiments of the invention, actuators may be positioned within the processing element carrier and configured to create localized deflections in the processing element, such as a polishing pad. These localized deflections may enhance the amount of material removal on the process side of the substrate opposite the localized deflection in the process element.

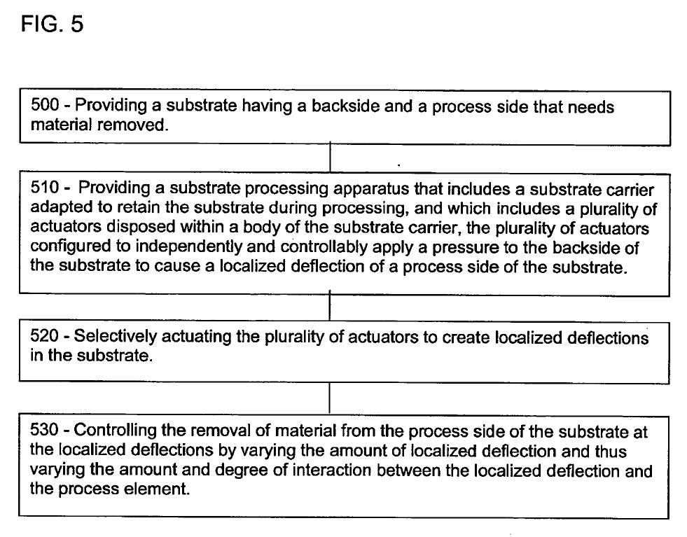

FIG. 5 illustrates a method of enhancing CMP using actuator to cause localized deflections in accordance with and embodiment of the present invention. A substrate may be provided having a backside and a process side in need of processing (500). A substrate processing apparatus may be provided that includes a substrate carrier adapted to retain the substrate during processing, and which may include a plurality of actuators disposed within the body of the substrate carrier, the plurality of actuators configured to independently and controllably apply a pressure to a backside of the substrate to cause at least a localized deflection of a process side of the substrate (510).

The plurality of actuators may be selectively actuated to create localized deflections in the substrate (520). The removal of material from the process side of the substrate at the localized deflections may be controlled by selectively varying the amount of localized deflections and thus varying the amount and degrees of interaction between the localized deflections and the process element (530).

In one embodiment of the present invention, substrate surface pattern information, such as lithography mask information, may accompany the particular substrate or lot of substrates to be processed. This information may be used by the controller of the processing apparatus to independently and/or collectively manipulate the actuators to control the planarization of the process side in order to enhance the localized processing, for example within die, die-to-die and within substrate planarization.

In one embodiment of the present invention, the actuators may also be equipped with temperature modulating capability to modulate local surface temperatures of the processing side of the substrate. This may allow for the creation of a difference in temperature in a local area or from one grouping of localized areas to another area of the surface by individually and/or collectively controlling the temperature modulation, which in turn may to enhance or suppress local removal rates. For example, the actuator may increase or decrease the temperature at one or more localized areas or groups of localized areas, while the temperature at other localized locations may be maintained or independently modulated.

Embodiments of the present invention may allow for he energy sources may be manufactured in a number of ways. In one embodiment, the actuators may be manufactured using micro machining technology and methodologies, such as Micro Electro Machining Systems.

Though certain substrate processing tool configurations were illustrated, embodiments of the present invention may also be applied to a number of different processing tool configurations and processes. Other tool configurations may include, but are not limited to, those having single processing elements, multiple processing elements, processing elements having simple and complex geometries, substrate holders having one or more electrically isolated regions, and/or multiple substrate holders.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

What is claimed is:

1. A substrate carrier adapted to retain a substrate during processing, comprising:
a body; and
a plurality of actuators at least partially disposed within the body, each of the plurality of actuators configured to independently and controllably apply a pressure to a backside of the substrate to cause a localized deflection of a process side of the substrate.

2. The substrate carrier of claim 1, wherein the plurality of actuators include at least one electrically driven actuator adapted to receive an electrical input.

3. The substrate carrier of claim 2, wherein the at least one electrically driven actuator is in electrical communication with an electricity source and includes an impingement pin adapted to be driven by a solenoid, the impingement pin having a first end adapted for forcible engagement with the backside of the substrate.

4. The substrate carrier of claim 2, further comprising a controller in electrical communication with the plurality of electrical actuators, the controller being configured to control an amount of deflection at a location on the process side of the substrate by varying the electrical input.

5. The substrate carrier of claim 1, wherein the plurality of actuators include at least one pneumatically driven actuator adapted to receive a pneumatic input.

6. The substrate carrier of claim 5, wherein the at least one pneumatically driven actuator is in pneumatic communication with a pneumatic source and includes a selectively chargeable cylinder and a piston, the piston having a first end adapted to forceably engage the backside of the substrate and the second end adapted to slidably engage the chargeable cylinder.

7. The substrate carrier of claim 5, further comprising a controller in pneumatic communication with the plurality of pneumatic actuators, the controller being configured to control an amount of deflection at a location on the process side of the substrate by varying the pneumatic input.

8. The substrate carrier of claim 1, wherein the plurality of actuators includes an actuator drive mechanism selected from a group consisting of a screw drive mechanism, a hydraulic drive mechanism and a magnetic drive mechanism.

9. The substrate carrier of claim 1, further comprising a controller in communication with the plurality of actuators, the controller being configured to control an amount of deflection at a location on the process side of the substrate.

10. The substrate carrier of claim 9, further comprising an endpoint detection device for monitoring the process side of the substrate during processing, the endpoint detection device being in communication with the controller, the controller being adapted to receive an input from the endpoint detection device representing an amount of material being removed from the process side of the substrate, and adapted to variably control the amount of localized deflection based at least in part on the received input.

11. A substrate processing system, comprising:
a processing piece adapted to hold a processing element and configured to facilitate mechanical and chemical interaction with a process side of a substrate;
a slurry delivery device adapted to dispense a slurry on the substrate to facilitate processing of the process side of the substrate; and
a substrate carrier configured to control the substrate for processing, the substrate carrier including a body and a plurality of actuators at least partially disposed within the body, the plurality of actuators configured to independently and controllably apply a pressure to a backside of the substrate to cause a localized deflection of the process side of the substrate toward the processing element to urge removal of material from the process side at the localized deflections.

12. The substrate processing system of claim 11 wherein the plurality of actuators includes at least one electrically driven actuator adapted to receive an electrical input.

13. The substrate processing system of claim 12, wherein the at least one electrically driven actuator is in electrical communication with an electricity source and includes an impingement pin adapted to be driven by a solenoid, the impingement pin having a first end adapted for forcible engagement with the backside of the substrate.

14. The substrate processing system of claim 12, further comprising a controller in electrical communication with the plurality of electrical actuators, the controller being configured to control an amount of deflection at a location on the process side of the substrate by varying the electrical input.

15. The substrate processing system of claim 11, wherein the plurality of actuators includes at least one pneumatically driven actuator adapted to receive a pneumatic input.

16. The substrate processing system of claim 15, wherein the at least one pneumatically driven actuator is in pneumatic communication with a pneumatic source and includes a selectively chargeable cylinder and a piston, the piston having a first end adapted to forcibly engage the backside of the substrate and the second end adapted to slidably engage the chargeable cylinder.

17. The substrate carrier of claim 15, further comprising a controller in pneumatic communication with the plurality of pneumatic actuators, the controller being configured to control an amount of deflection at a location on the process side of the substrate by varying the pneumatic input.

18. The substrate processing system of claim 11, wherein the plurality of actuators includes an actuator drive mechanism selected from a group consisting of a screw drive mechanism, a hydraulic drive mechanism and a magnetic drive mechanism.

19. The substrate processing system of claim 11, further comprising a controller in communication with the plurality of actuators, the controller being configured to control the an amount of deflection at a location on the process side of the substrate.

20. The substrate processing system of claim 19, further comprising an endpoint detection device for monitoring the process side of the substrate during processing, with the endpoint detection device being in communication with the controller, and the controller being adapted to receive an input from the endpoint detection device representing an amount of material being removed from the process side of the substrate, and to variably control the amount of localized deflection based at least in part on the received input.

21. The substrate processing system of claim 11, wherein the substrate is a semiconductor material having at least one metalized layer on the process side, and the processing piece includes at least one polishing element configured to planarize the at least one metalized layer.

22. The substrate processing system of claim 11, wherein the plurality of actuators include at least one electrically driven actuator and at least on pneumatically driven actuator.

23. A substrate processing apparatus, comprising:
a substrate carrier adapted to retain a substrate during processing; and
a processing element carrier adapted to carry a processing element in a substantially opposing relationship with the substrate, the processing element including a plurality of actuators at least partially disposed within the processing element, each of the plurality of actuators configured to independently and controllably apply a pressure to a backside of the processing element to cause a localized deflection of a process side of the process element.

24. The substrate processing apparatus of claim 23, wherein the plurality of actuators includes an actuator drive mechanism selected from a group consisting of a pneumatic drive mechanism, electrical drive mechanism, screw drive mechanism, a hydraulic drive mechanism and a magnetic drive mechanism.

25. The substrate processing apparatus of claim 23, further comprising a controller in communication with the plurality of actuators, the controller being configured to control the an amount of deflection at a location on the process side of the process element.

26. A substrate processing method, comprising:
providing a substrate having a backside and a process side;
providing a substrate processing apparatus that includes a processing piece adapted to facilitate mechanical and chemical interaction with the substrate, and a substrate carrier that includes a plurality of actuators disposed within a body of the substrate carrier, the plurality of actuators configured to independently and controllably apply a pressure to a backside of the substrate to cause a localized deflection of a process side of the substrate;
selectively actuating one or more of the plurality of actuators to create the localized deflection in the substrate; and
controlling removal of material from the process side of the substrate at the localized deflection by controlling the amount of the localized deflection in the substrate.

27. The method of claim 26, wherein the selectively actuating one or more of the plurality of actuators include using an electrically driven actuator actuated by a solenoid, and varying an electrical input to the solenoid to vary the amount of the localized deflection caused by the actuator.

28. The method of claim 26, wherein the selectively actuating or more of the plurality of actuators include using a pneumatically driven actuator driven by a pneumatic source, and varying an amount of air supplied by the pneumatic source to the pneumatically actuated actuator to vary the amount of the localized deflection caused by the actuator.

29. The method of claim 26, wherein the controlling removal of material from the process side of the substrate includes reducing the amount of the localized deflection to reduce the amount of material removed from the process side of the substrate.

30. The method of claim 26, further comprising:
coupling an endpoint detector to the substrate processing apparatus adapted to monitor the amount of material that has been removed from the process side of the substrate;
coupling a controller to the endpoint detector and the plurality of actuators; and
selectively controlling an amount of input to the actuator based at least in part on an output of the endpoint detector.
